(19) United States
(12) Patent Application Publication
(10) Pub. No.: US 2003/0034165 A1
(43) Pub. Date: Feb. 20, 2003

(54) Method and apparatus for external grounding of plastic backshell connectors

(75) Inventors: George W. Brehm, Holmes, NY (US); Robert L. Nicoletti, Milton, NY (US)

Correspondence Address: Sean F. Sullivan, Esq., Cantor Colburn LLP, 55 Griffin Road South, Bloomfield, CT, 06002, US

(73) Assignee: INTERNATIONAL BUSINESS MACHINES CORPORATION, ARMONK, NY (US)

(21) Appl. No.: 09/933,098

(22) Filed: Aug. 20, 2001

(51) Int. Cl. H05K 9/00

(52) U.S. Cl. 174/35 C

(57) ABSTRACT

A shielding system for an electrical cable terminating at an electrical connector is disclosed. In an exemplary embodiment of the invention, the system includes a backshell assembly having an upper half and a lower half adapted to be mated with one another. A can assembly is configured within the backshell, the can assembly having upper and lower halves corresponding to the backshell assembly. The can assembly further includes an extended portion extending beyond a front end of the backshell assembly, wherein the can assembly provides a ground connection from a shield within the cable to the connector.

### BACKGROUND

The present invention relates generally to electrical connector devices and, more particularly, to a method and apparatus for external grounding and shielding of plastic backshell connectors.

Electrical connectors are mated together in a number of different applications in order to provide an electrical interface between conductors or circuits coupled to the electrical connectors. In certain applications, an electrical connector is adapted to receive a plurality of individual wires that are coupled to electrical contacts within the electrical connector. One end of each of the electrical contacts is coupled to one of the conductors extending into the electrical connector with the other end of the contact being adapted to engage a contact in the electrical connector with which it is to be mated. While the electrical connector used with such individual conductors may have a number of different configurations, it typically includes a backshell or housing with four sidewalls extending between a front mating end and a rear wire receiving end. The plurality of conductors to be coupled to the contacts in the electrical connector can be inserted into the wire receiving end of the electrical connector and coupled to the individual ones of the electrical contacts.

The use of plastic as the backshell material is a desirable option, since molded plastic is much less expensive than an all-metal backshell. But, in applications such as computer operating systems, FCC noise and shielding requirements typically require grounded/shielded UPIC cables for a “non-raised floor” environment. Thus, a metal shield may be used as an EMI/RFI shield to insure that noise signals or other interference that may be present near the electrical connectors do not interfere with the signals being processed through those connectors and that the signals being processed through those connectors do not interfere with electrical components near the connectors.

Existing designs of UPIC cables used in high-voltage applications (e.g., 600 volts), however, employ all-plastic backshells that generally do not provide the sufficient shielding effectiveness described above. On the other hand, the traditional metal shielding implementations used in low-voltage applications (e.g., metallic coating, sputtering, taping, overmolding, etc.) are generally incompatable with the high-voltage applications due to creepage and clearance requirements associated therewith.

### BRIEF SUMMARY

The foregoing discussed drawbacks and deficiencies of the prior art are overcome or alleviated by a shielding system for an electrical cable terminating at an electrical connector. In an exemplary embodiment of the invention, the system includes a backshell assembly having an upper half and a lower half adapted to be mated with one another. A can assembly is configured within the backshell, the can assembly having upper and lower halves corresponding to the backshell assembly. The can assembly further includes an extended portion extending beyond a front end of the backshell assembly, wherein the can assembly provides a ground connection from a shield within the cable to the connector.

In a preferred embodiment, the backshell assembly is a non-conductive material and the can assembly is a conductive material. The can assembly is insert molded into the backshell assembly. One of the upper and lower halves of the can assembly has an outer diameter less than an inner diameter of the other of the upper and lower halves of the can assembly. Preferably, a portion of one of the upper and lower halves of the can assembly overlaps with a portion of the other of said upper and lower halves of the can assembly, when mated together.

In an alternative embodiment, the extended portion of the can assembly extends through an opening in the front end of the backshell assembly. A first pair of extended portions extends from the upper half of the can assembly, and a second pair of extended portions extends from the lower half of the can assembly. Thereby, the first pair of extended portions are brought into electrical contact with the second pair of extended portions.

### BRIEF DESCRIPTION OF THE DRAWINGS

Referring to the exemplary drawings wherein like elements are numbered alike in the several Figures:

FIG. 1 is a side elevational view of a shielding system for an electrical cable terminating in an electrical connector, in accordance with an embodiment of the invention;

FIG. 2 is a front end view of the shielding system, shown in an assembled state upon the electrical cable and connector; and

FIG. 3 is another side elevational view of the shielding system of FIG. 1, shown in an assembled state.

### DETAILED DESCRIPTION

Referring generally to the Figures, there is shown a shielding system 10 for an electrical cable 12 terminating in an electrical connector 14, in accordance with an embodiment of the invention. In the embodiment depicted, system 10 is particularly adapted for use with UPIC (Universal Power Interconnect and Communication) cables found in IBM S390® computer systems. However, it will be appreciated that the present invention embodiments are equally applicable to other electrical connector systems where external grounding and EMI shielding are prevalent concerns.

As shown most particularly in FIG. 1, system 10 includes a backshell assembly 16 having an upper half 18 and a lower half 20 adapted to be mated with one another, in order to house an open end of cable 12 and a portion of connector 14 therein. The cable 12 includes a plurality of individual conductors 22 (which may include both power and signal conductors) that are “fanned out” and coupled with corresponding individual electrical contacts (not shown) located inside a plurality of individual housings or silos 24 in connector 14. The silos 24 are constructed of a material such as plastic, and are configured to insulate and protect a series of mating male pins from a connecting device (not shown) to be plugged into the contacts. A retention latch 25 may also be included on the top half of connector 14 for retaining a mating connecting device that is plugged into connector 14.

A pre-molded grommet 26 or plastic insert is provided around the end of cable 12 for strain relief purposes, with the grommet 26 intended to abut the interior of a back end 28 of backshell assembly 16. The cable 12 further includes a braided shield 30, extending out of the end thereof and pulled back over grommet 26. The normally grounded braided shield 30 surrounds the individual conductors 22 within cable 12, thereby providing a shield for the conductors 22. As will be explained later, the exposed portions of braided shield 30 are intended to be placed in electrical contact with a frame ground at the front of connector 14.

The backshell assembly 16 is preferably made of a non-conductive material (e.g., molded plastic) and may be found in use with existing UPIC cable connectors. Such existing connectors, as mentioned previously, do not (by themselves) provide for an external grounding scheme which shields electrical noise emanating, for example, from a power subsystem. Thus, system 10 further includes a conductive metal can assembly 32 configured within backshell assembly 16. As is the case with backshell assembly 16, the can assembly 32 also includes an upper half 34 and a lower half 36. The upper and lower halves 34, 36 of can assembly 32 are designed to be insert-molded within the interior of upper and lower halves 18, 20, respectively, of backshell assembly 16.

Because upper and lower halves 34, 36 of can assembly 32 are intended to be brought into physical and electrical contact with one another, a lip 37 is provided on upper half 34, so as to provide a contact surface with lower half 36. Alternatively, the lip 37 may be located on lower half 36. In addition, the upper and lower halves 34, 36 are dimensioned such that an outer diameter of one of the halves is less than an inner diameter of the other of the halves. In other words, a part of the upper half 34 of can assembly 32 is made to snugly fit within a part of the lower half 36 of can assembly 32, or vice versa.

In order to complete a conductive path from braided shield 30 to a frame ground (not shown) of a corresponding mating electrical component (not shown), can assembly 32 further includes a plurality of extension portions 38, extending from a front end thereof. Extension portions 38 are located on opposing sides with respect to silos 24, as well as on both upper and lower halves 34, 36 of can assembly 32. In addition, extension portions 38 are the only portions of can assembly 32 that reside outside backshell assembly 16, and protrude therethrough from openings 40 located within corresponding surfaces of backshell assembly 16.

The opposing halves of backshell assembly 16, along with opposing halves of can assembly 32 may be mated and secured to one another by a fastening mechanism, such as a screw 42, which protrudes through an opening (not shown) in the upper half 18 of backshell assembly 16 and the upper half 34 of can assembly 32. A threaded post 44 is configured within the lower half 20 of backshell assembly for receiving the screw 42 therein. A plurality of guideposts 46 in lower half 20 are also optionally provided to ensure proper alignment of the upper and lower halves 18, 20 of backshell assembly 16.

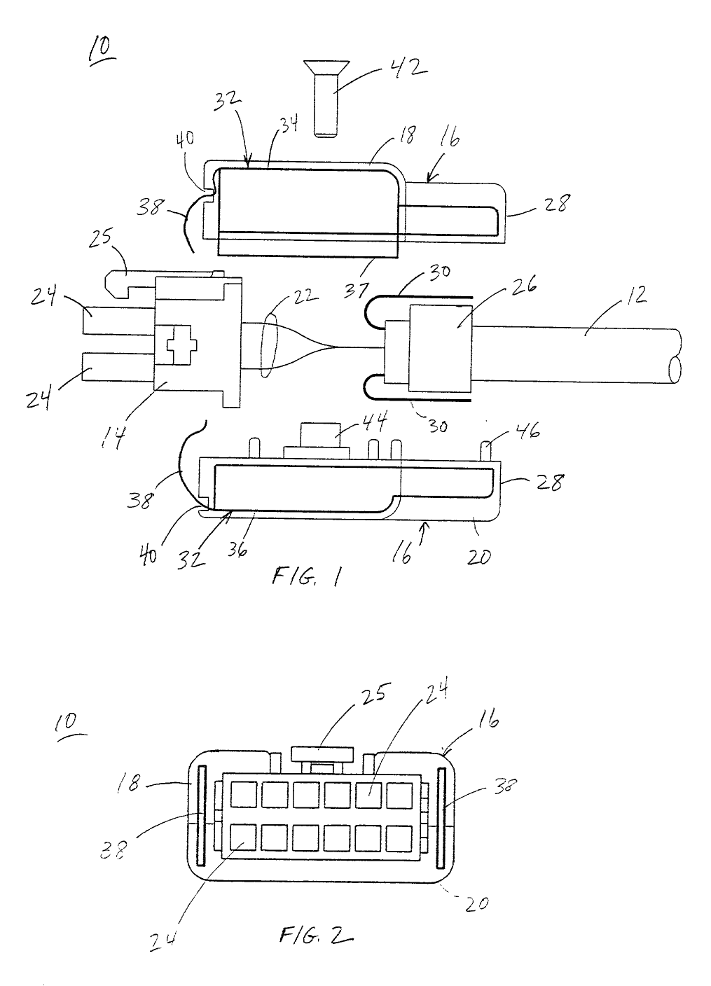

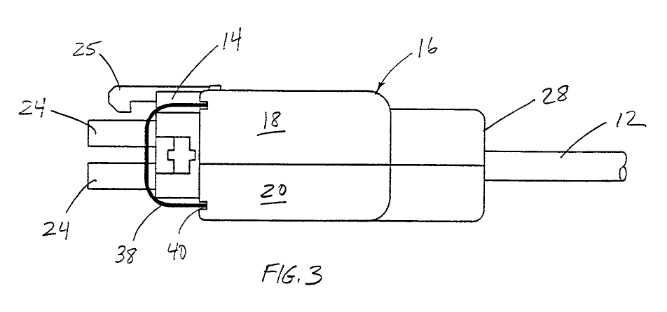

When the backshell assembly 16 (with can assembly 32 therein) is assembled around cable 12 and connector 14, opposing (i.e., upper and lower) extension portions 38 on both sides of silos 24 are brought together in physical and electrical contact with one another in an overlapping fashion, as is shown in FIGS. 2 and 3. When the connector 14 is mated with a corresponding electrical component (not shown), the extension portions 38 are compressed together to form a continuous conducting loop which extends from the upper and lower halves 18, 20 of backshell assembly 16.

In addition, the mating of upper and lower halves 18, 20 of backshell assembly also causes surfaces of the upper and lower halves 34, 36 of can assembly 32 to be brought into physical and electrical contact with exposed portions of braided shield 30. A continuous grounding path is thereby formed from braided shield 30, through the interior portions of can assembly 32 (i.e., interior with respect to backshell assembly 16), to the extension portions 38 of can assembly 32 residing outside backshell assembly, and finally to a frame ground (not shown) in a corresponding electrical component (not shown) adapted to make electrical contact with extension portions 38.

Thus configured, shielding system 10 provides both effective noise shielding from a source of radiated noise and external grounding to a frame ground, without foregoing the use of a less expensive plastic backshell assembly. Furthermore, the present embodiments provide the shielded ground connection while still maintaining satisfactory creepage and clearance distance applicable to higher voltage applications. As a further benefit, the use of additional insulative measures, such as taping of conductive surfaces, is avoided by the cable assembler.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A shielding system for an electrical cable terminating at an electrical connector, the system comprising:
a backshell assembly having an upper half and a lower half adapted to be mated with one another;
a can assembly configured within said backshell, said can assembly having upper and lower halves corresponding to said backshell assembly; and
said can assembly further including having an extended portion extending beyond a front end of said backshell assembly;
wherein said can assembly provides a ground connection from a shield within the cable to the connector.

2. The shielding system of claim 1, wherein:
said backshell assembly comprises a non-conductive material; and
said can assembly comprises a conductive material.

3. The shielding system of claim 2, wherein said can assembly is insert molded into said backshell assembly.

4. The shielding system of claim 1, wherein one of said upper and lower halves of said can assembly has an outer diameter less than an inner diameter of the other of said upper and lower halves of said can assembly.

5. The shielding system of claim 4, wherein a portion of said one of said upper and lower halves of said can assembly overlaps with a portion of said other of said upper and lower halves of said can assembly, when mated together.

6. The shielding system of claim 1, wherein said extended portion of said can assembly extends through an opening in said front end of said backshell assembly.

7. The shielding system of claim 1, further comprising:
a first pair of extended portions extending from said upper half of said can assembly; and
a second pair of extended portions extending from said lower half of said can assembly.

8. The shielding system of claim 7, wherein said first pair of extended portions are brought into electrical contact with said second pair of extended portions.

9. A method for electrically shielding an electrical cable terminating at an electrical connector, the method comprising:
adapting a backshell assembly having an upper half and a lower half to be mated with one another;
configuring a can assembly within said backshell, said can assembly having upper and lower halves corresponding to said backshell assembly; and
extending an extended portion of said can assembly beyond a front end of said backshell assembly;
wherein said can assembly provides a ground connection from a shield within the cable to the connector.

10. The method of claim 9, wherein:
said backshell assembly comprises a non-conductive material; and
said can assembly comprises a conductive material.

11. The method of claim 10, wherein said can assembly is insert molded into said backshell assembly.

12. The method of claim 9, wherein one of said upper and lower halves of said can assembly has an outer diameter less than an inner diameter of the other of said upper and lower halves of said can assembly.

13. The method of claim 12, wherein a portion of said one of said upper and lower halves of said can assembly overlaps with a portion of said other of said upper and lower halves of said can assembly, when mated together.

14. The method of claim 9, wherein said extended portion of said can assembly extends through an opening in said front end of said backshell assembly.

15. The method of claim 9, further comprising:
extending a first pair of extended portions from said upper half of said can assembly; and
extending a second pair of extended portions from said lower half of said can assembly.

16. The method of claim 15, wherein said first pair of extended portions are brought into electrical contact with said second pair of extended portions.
